(19) United States
(12) Patent Application Publication
(10) Pub. No.: US 2012/0042928 A1
(43) Pub. Date: Feb. 23, 2012

(54) OUTDOOR PHOTOVOLTAIC GENERATOR

(76) Inventor: Bernhard BECK, Dimbach (DE)

(21) Appl. No.: 13/214,541

(22) Filed: Aug. 22, 2011

(30) Foreign Application Priority Data
Aug. 20, 2010 (DE) 10 2010 035 000.1

(51) Int. Cl. H01L 31/042

(52) U.S. Cl. 136/244

(57) ABSTRACT

An outdoor photovoltaic generator is provided that has a plurality of straight, parallel rows of rectangular photovoltaic modules that are located on a substructure, each of which comprises a plurality of photovoltaic cells. The photovoltaic cells are arranged on each photovoltaic module such that, in the event of a shading extending parallel to an edge of the photovoltaic module, the energy conversion and transport function of the remaining, unshaded photovoltaic cells or photovoltaic cell regions of the photovoltaic module is maintained. The substructure provides equal inclination of the photovoltaic modules with respect to south. The rows with respect to the east-west direction are installed rotated at an angle between 10° and 40° toward the northeast or toward the northwest. In exchange for acceptance of a reduction in the total output of photovoltaically produced energy as seen over the course of the day, the arrangement permits a displacement of the maximum output to a time of day other than 12:00 noon.

This nonprovisional application claims priority under 35 U.S.C. §119(a) to German Patent Application No. DE 10 2010 035 000.1, which was filed in Germany on Aug. 20, 2010, and is herein incorporated by reference.

### BACKGROUND OF THE INVENTION

1. Field of the Invention

The invention relates to an outdoor photovoltaic generator with a plurality of straight, parallel rows of rectangular photovoltaic modules that are located in a fixed manner on a stationary substructure, and each of which comprises a single string or multiple strings of series-connected photovoltaic cells, the ends of which form a first and a second output pole of the photovoltaic module.

The invention additionally relates to outdoor photovoltaic generators of the above-mentioned type in which the rows of rectangular photovoltaic modules have gaps, so that each row includes groups of photovoltaic modules.

2. Description of the Background Art

An outdoor generator can be understood to be a system (such as a roof-mounted system) that does not provide protection from weather, and accordingly can also be permeable to rain water so as not to seal off the soil underneath it. Insofar as the terrain permits, systems of this type are aligned in such a manner that the rows of photovoltaic modules (PV modules) extend in the east-west direction and the normal line to the module surface is oriented in the south direction. The inclination of the modules to the horizontal differs in turn as a function of the installation location of the PV generator. This installation permits the generation of the maximum quantity of energy, integrated over the day, under the prevailing weather conditions.

Rotating the rows out of the east-west axis (corresponding to an orientation of the PV modules out of the south direction) would lead to a reduced output, which results firstly from the overall less favorable orientation of the PV modules with respect to the sun. Secondly, in the case of an early, low sun position, the PV modules are illuminated from their backs or undersides, and in the case of a late, low sun position, shading takes place in such a manner that the top edge of the inclined photovoltaic modules would cover the bottom edge of a row located behind it.

When classic photovoltaic modules are used, with a matrix having a plurality of series-connected photovoltaic cells arranged in a serpentine pattern on the module surface, this shading has the disadvantageous effect that the darkening increases the electrical resistance of the shaded cells. This effect can lead to a cessation of the photovoltaically generated DC current. Due to the series connection of the photocells, even a single non-conducting cell affects the current flow of the entire cell string. Thus, even a single leaf that completely covers one of the photovoltaic cells results in dropout of the entire PV module.

Recent developments in module technology have led to a PV module in which the individual cells extend over the entire edge length of the PV module from one border of the PV module to the other. With such a module, if each cell is partially shaded, only a dropout of generated energy corresponding to the affected area of the shading occurs, and not a complete dropout.

### SUMMARY OF THE INVENTION

It is therefore an object of the invention to structure an incoming supply of photovoltaically generated energy in outdoor systems without sun position tracking in such a manner that compensation on the part of the energy supplier can be optimized.

This object is attained according to an embodiment of the invention in the case of photovoltaic modules with a single string by the means that the photovoltaic cells are arranged on each photovoltaic module such that each photovoltaic cell of the string experiences equal shading in the event of a shading extending parallel to the bottom edge of the photovoltaic module. Moreover, the substructure provides equal inclination of all photovoltaic modules relative to the horizontal. Furthermore, the photovoltaic modules are oriented at an angle between 10° and 40° toward the southwest or toward the southeast.

In, for example, the case of PV modules having multiple strings, the object is attained in that the photovoltaic cells are arranged on each PV module such that each photovoltaic cell of the string experiences equal shading in the event of a shading extending parallel to the bottom edge of the PV module. The substructure, in turn, provides equal inclination of all PV modules relative to the horizontal, and the PV modules, in turn, are oriented at an angle between 10° and 40° toward the southwest or toward the southeast.

When one or more gaps are present between PV modules of a row, the object can be attained with regard to the first module type in that the photovoltaic cells are arranged on each PV module such that, for at least a portion of the PV modules in a group, each photovoltaic cell of the string experiences equal shading in the event of a shading extending parallel to the bottom edge of the PV module. The substructure once again provides equal inclination of all PV modules relative to the horizontal, and the PV modules are likewise oriented at an angle between 10° and 40° toward the southwest or toward the southeast.

With regard to the second module type, provision can be made for the photovoltaic cells to be arranged on each PV module such that, for at least a portion of the PV modules in the same group, all photovoltaic cells of the same string experience equal shading in the event of a shading extending parallel to the bottom edge of the PV module. The substructure once again provides equal inclination of all PV modules relative to the horizontal, and the PV modules are oriented at an angle between 10° and 40° toward the southwest or toward the southeast.

In this regard, a row can be understood to mean any arrangement of PV modules in a planar surface extending longitudinally. The property of planarity or flatness does not apply in a mathematical sense, but instead can include a certain curvature in adapting to the terrain. The row can either be continuous without interruptions, or can have gaps. This corresponds to a subdivision of a row into sections or groups. Minimal installation-related spacings of a few millimeters or centimeters are not to be considered as interruptions or gaps in this regard.

The present invention proceeds from the concept that in countries with hot climatic conditions, the time period of greatest heating of building interior spaces does not occur until the afternoon. Accordingly, the greatest energy demand from air conditioners is not at 12:00 noon with the highest sun position, but instead is only at a later time, for example 3:00 P.M.

Since air conditioners represent a large fraction of total energy consumption, obtaining electrical energy in the afternoon is more cost-intensive than in the morning. Accordingly, the compensation that the energy suppliers are prepared to pay for generated electricity is higher at peak load times than at light load times.

The table reproduced below shows an example of an actual rate structure of an energy supplier in the USA.

TABLE 1
Compensation rates for solar electricity as a function of time of day

| Time of | | | | |
|---|---|---|---|---|
| Delivery | Months | Super Peak | On Peak | Off Peak |
| Summer | Jun.-Sep. | 2:00 to 8:00 P.M. | 6:00 A.M. to. | all other |
| | | | 2:00 P.M | hours |
| | | Mon-Sat | 8:00 P.M. to | |
| | | except holidays | 10:00 P.M. | |
| | | | Mon-Sat except | |
| | | | holidays | |
| Fall & | Oct.-Feb. | | | |
| Winter | | | | |
| Spring | Mar.-May | | | |

| | |
|---|---|
| Holidays | New Years, July 4^{th}, Memorial Day, |
| | Labor Day, Thanksgiving, Christmas |

| Time of Use Period | 10-Year |
|---|---|
| Winter Off Peak | $0.0731 |
| Winter On Peak | $0.0916 |
| Winter Super Peak | $0.1103 |
| Spring Off Peak | $0.0628 |
| Spring On Peak | $0.0751 |
| Spring Super Peak | $0.0836 |
| Summer Off Peak | $0.0793 |
| Summer On Peak | $0.0875 |
| Summer Super Peak | $0.2951 |
| Annual Average | $0.1065 |

With the background knowledge of the above-described, new technology for photovoltaic cells, this intentional misalignment of the outdoor system no longer has the effect of a dramatic output reduction during the periods of sun position when the inclination and misalignment to the south result in shading of a part of the PV module.

In this context, one can proceed from the premise that the shading parallel to the edge or border of the PV module extends across the entire width of the PV module. This is the case for all PV modules in the row except for the first—or, depending on the direction of view, the last—PV module in each row. One of the two PV modules will be subjected to shading that does not extend over the entire width, which likewise results in reduced output from the PV module at the beginning or end of the row.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a diagram of the profile of photovoltaically generated output over the time of day,

FIG. 2 is a schematic view of three PV module rows in the classic east-west orientation,

FIG. 3a-3e are a schematic side view for FIG. 2 at different times of day,

FIG. 4 is a schematic view of three PV module rows rotated by 30°,

FIG. 5a-5e are a schematic side view for FIG. 4 at different times of day,

FIG. 6a-6c are various PV module types that are suitable for use in a rotated photovoltaic system, and

FIG. 7 is an embodiment with gaps within a module row.

### DETAILED DESCRIPTION

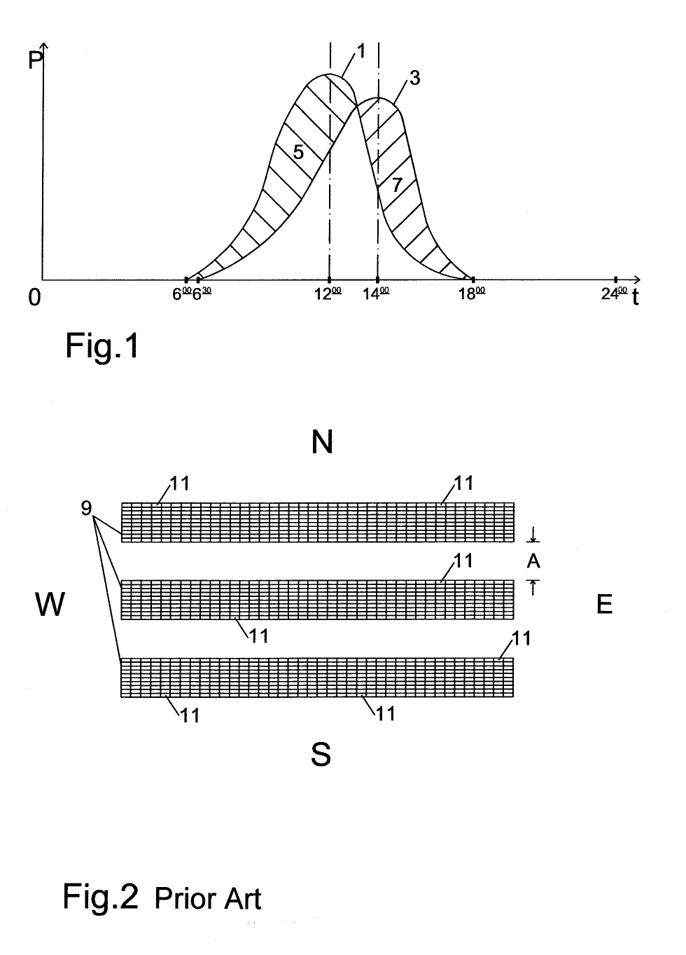

In FIG. 1, which will be used to describe the a desired effect in detail, the photovoltaically generated energy E is plotted over the time of day t. For the sake of simplicity, a time period between 6:00 A.M. and 6:00 P.M. is considered here. At 12:00, the sun is at its highest point, and the PV generator is delivering its maximum output. The behavior of the output or delivered energy E is plotted as a thin line 1. To the left and right of the maximum, the curve has a largely symmetrical shape according to a Gaussian distribution.

A rotation of the PV generator by, e.g., 30° toward the northeast has the effect that, in the case of a low sun position at 6:00 A.M., at first only the back of the PV modules is illuminated, and only later at, e.g., approximately 6:30 A.M., does the top of the PV modules receive sufficient solar energy to start feeding power to the grid. This effect is illustrated in the path of the curve along the thick line 3, in that the power feed starts later.

Line 3 additionally makes clear that the energy yield at the beginning will also be lower than without the rotation on account of the worsened angle between the module surfaces and the sun. The further path of the curve of line 3 shows that, as a result of the rotation by 30° from the point of view of the PV generator, the maximum irradiated power is shifted by three hours to 3:00 P.M., where the curve or line 3 reaches its maximum. In the evening hours, the effect arises that the bottom edge of each PV module row (except for the westernmost row) is shaded by the top edge of the PV module row adjacent to it on the west. Nonetheless, the irradiated power will always lie above the curve 1, since the loss of effective module area caused by the shading is overcompensated by the more favorable angle of the PV modules to the sun with the associated higher incident energy on the remaining module area.

Also shown in FIG. 1 is a thinly hatched, first region 5, the area of which corresponds to the integral of the reduced output over time t. The reduced output is the result of the less favorable orientation of the PV generator rows to the sun during the morning because of the rotation and the later start of energy generation.

Conversely, in the afternoon the PV generator rows are aligned more favorably to the sun than without the 30° rotation, thus resulting in an increased energy yield as compared to the customary east-west alignment. The size of this increased yield in the afternoon is illustrated by a second region 7, which is hatched with thick lines.

It is evident that the first region 5 has a larger area than the second region 7. The difference between the two regions 5 and 7 corresponds to the reduction in total energy E produced by the PV generator. However, this reduction in energy E is compensated from an economic standpoint by the higher revenue from the energy delivered in the afternoon as compared to the energy delivered in the morning. When considered in sum, therefore, more revenue is taken in on account of the higher energy price in the afternoon than is foregone as a result of the reduced delivery in the morning.

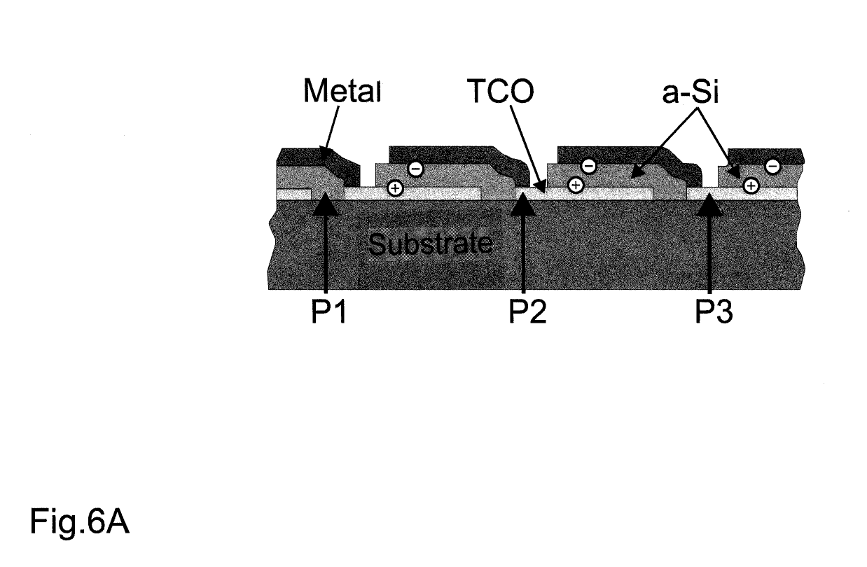

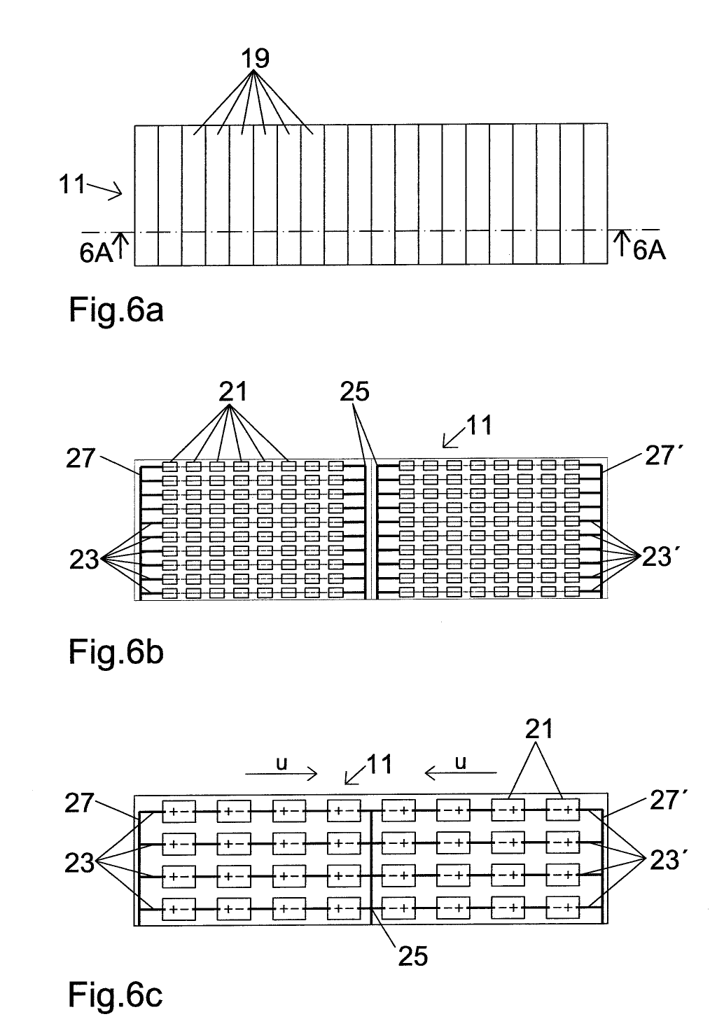

FIG. 2 shows three rows 9 of photovoltaic modules 11 of an outdoor system that extend along the east-west axis in the customary way. Each row can be up to several hundred meters long and have thousands of PV modules 11 of a type that is described below with reference to FIGS. 6a through 6d. The PV modules 11 are inclined towards the south by an angle α, wherein the inclination varies depending on the installation location. In the regions of Central Europe, the inclination is approximately 25°. The angle α defines the angle of incidence of the sun's rays on the PV modules, and generally is selected such that the sun's rays strike perpendicular to the module surfaces at the highest position of the sun at 12:00.

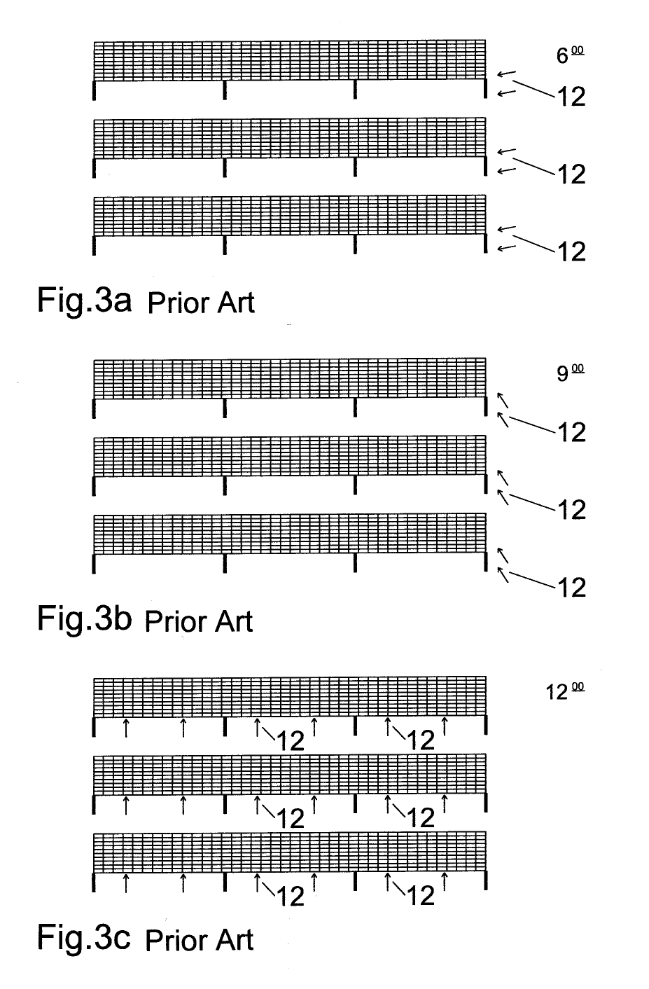

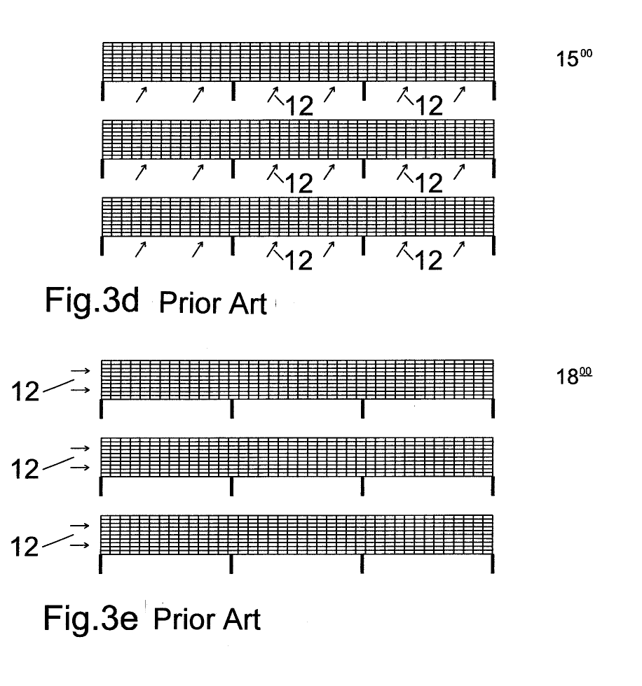

FIG. 3a through 3e are side views of the three rows 9 at different sun positions. In these figures, the arrows 12 show only the direction vector that corresponds to the components of the radiation parallel to the plane of the drawing. Accordingly, the shallow arrows 12 in FIG. 3a have only a small north-south component at 6:00 A.M., but a relatively large east-west component. Around 9:00 A.M., the sun has traveled far enough that its rays strike the photovoltaic modules at a steeper angle. The angle of incidence improves continuously as the sun climbs higher, until at 12:00 noon the arrows point only in the north-south direction and the rays are incident perpendicular to the modules.

The third component—not shown—of the vector 12, which is three-dimensional per se, would represent the sun position, which is low at morning and evening and is highest at midday. After the zenith has been passed, the rays are again incident more shallowly on the PV modules, but then from the western direction. This is shown with the aid of FIG. 3d, which shows an estimated sun position near 3:00 P.M. When the sun is going down at 6:00 P.M. as shown in FIG. 3e, the sun's rays are again incident on the modules from the west at a shallow angle.

The PV system orientation represented symbolically in FIGS. 2 and 3 allows for the maximum output that can be provided by the system under the prevailing weather conditions: No shadowing caused by the design takes place, and the alignment is optimized.

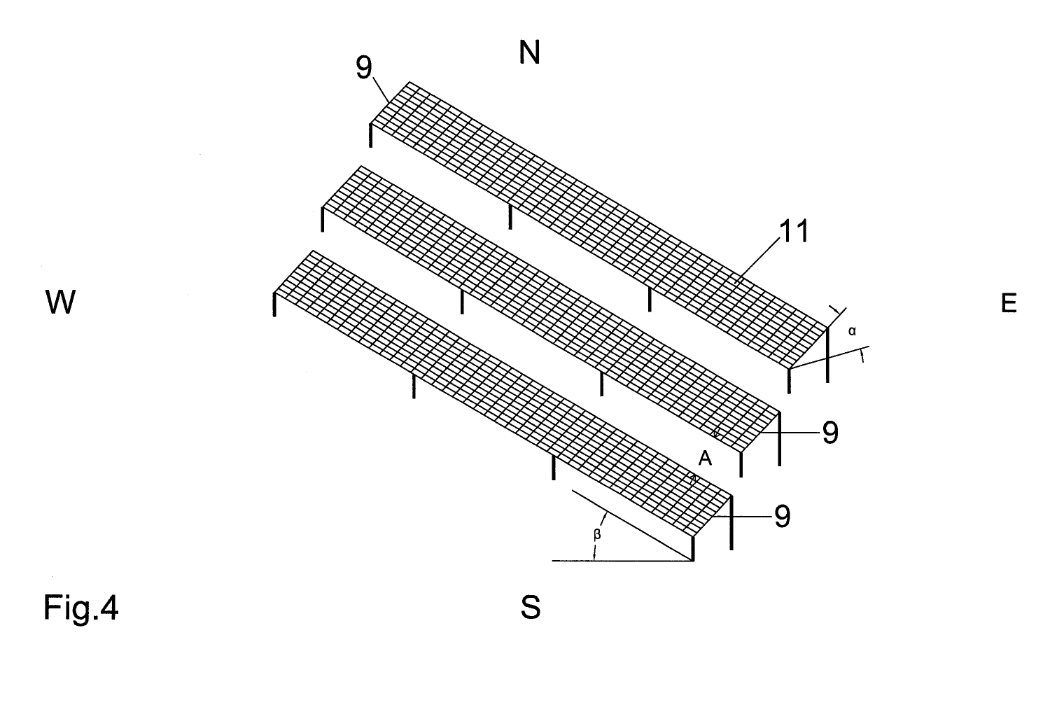

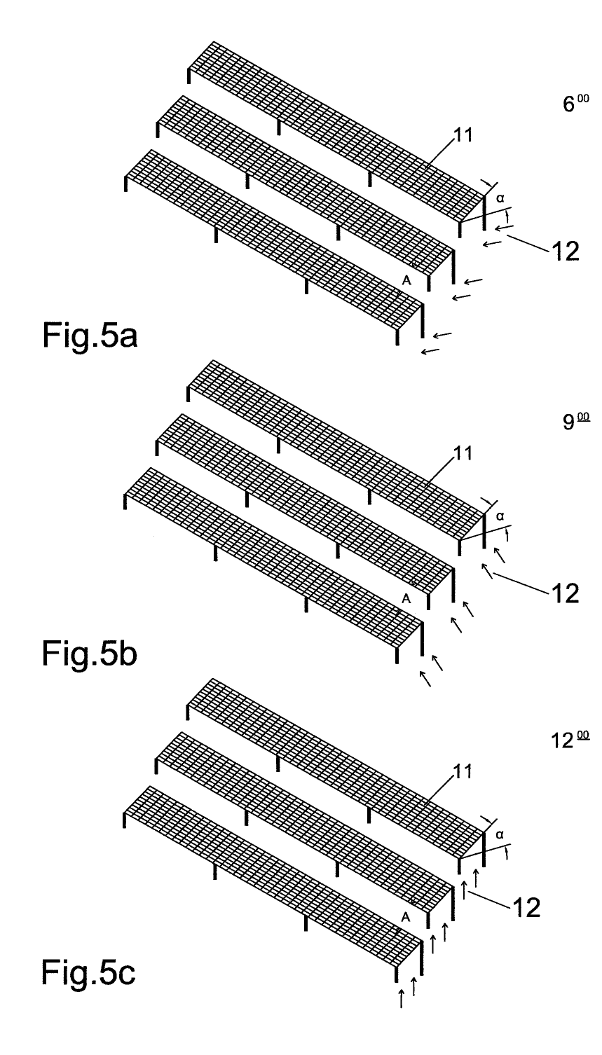

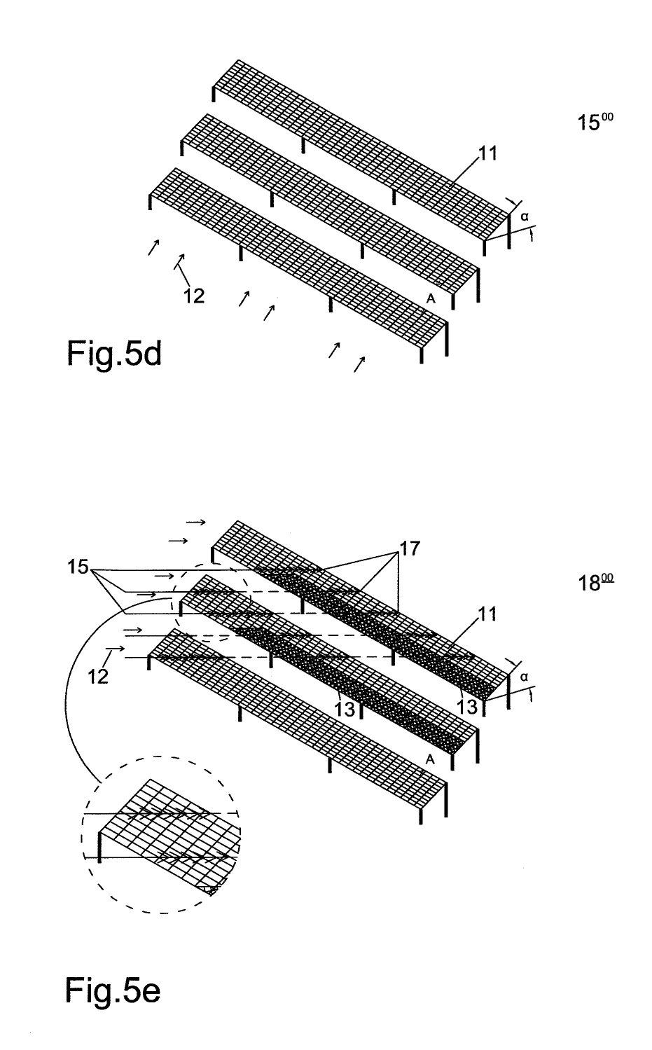

FIG. 4 shows an installation of the PV rows 9 that deviates from the classic orientation. The rows 9 are rotated by 30° toward the northeast, with the result that the installed PV modules 11 likewise lose their orientation to the south by 30°. As a result, less total solar energy is incident on the module surfaces, as is evident from FIGS. 5a to 5e.

It is evident from FIG. 5a that after sunrise in the east, the back of the PV modules 11 is initially irradiated. Incidence on the module surface will thus be delayed in time. As shown in FIG. 5b, solar incidence is present on all module surfaces, but at a less favorable angle as compared to the nonrotated system from the corresponding FIG. 3b. At 12:00 noon, which is to say at a time when the nonrotated system from FIG. 3c achieves its maximum output, the output of the rotated system corresponding to FIG. 5c is rising, since the 30° rotation only causes inclined incidence of the sun's rays on the PV modules 11.

The output generation improves continuously as the sun travels until, three hours later at 3:00 P.M., the sun is slightly lower than at noon, but is incident perpendicular to the PV module surfaces. The maximum of the photovoltaically generated output is now achieved, as is evident from FIG. 5d.

As the sun falls further, the angle increasingly becomes more favorable than in the nonrotated case, so that the line 3 in FIG. 1 is always above the line 1 there. Then, late in the evening, the shading effect at late, low sun positions begins to occur, as indicated in FIG. 5e by the hatched regions 13. The sun's rays here are symbolized by the arrowed lines 15, whose arrow heads 17 represent the point of incidence of the rays on the PV modules 11. Accordingly, no arrow heads are present in the shaded area 13.

The times of day and angles of incidence selected were chosen solely for purposes of clear explanation, and are not part of the present technical teaching.

FIGS. 6a to 6d show examples of photovoltaic modules 11 such as are suitable for use with the present invention. FIG. 6a shows a module 11 with what is called a TCO layer as the layer forming the electrical contact between the individual cells. In this design, the individual cells are present in the form of stripes 19, wherein the TCO layer is likewise placed in stripes over the entire module width or module length. This is evident in auxiliary FIG. 6A, which depicts a cross-section through FIG. 6a. The stripes are perpendicular to the direction of the rows 9, hence extend from top to bottom. If a region is shaded in this module type, the unshaded regions continue to function, and the charge they generate is carried away by the contact layers and made available to the inverter unhindered by the shaded areas. FIG. 6b shows the same state of affairs with stripes 19 extending parallel to the rows 9.

FIG. 6b shows how individual conventional photovoltaic cells 21 extend from edge to edge of the photovoltaic module 11. In this design they form strings 23 that are oriented parallel to the direction of the rows 9. Contact is made with the strings 23 on both lateral edges of the PV module 11. Thus, as a result the photovoltaic cells of each string 23 are electrically connected in series, and multiple strings 23 of a photovoltaic module 11 are electrically connected in parallel. If one of the strings 23 is now shaded, the remaining, unshaded strings 23 continue to function unaffected.

FIG. 6c shows a variation of this embodiment. On the PV module 11 there, the photovoltaic cells 21 of the photovoltaic module 11 are subdivided into multiple strings 23, 23′ extending from edge to edge. The two string blocks shown have opposite pole orientations in this design. Thus, a central contact electrode 25 in cooperation with two edge electrodes 27, 27′ can establish the photovoltaically generated DC voltage U in each case.

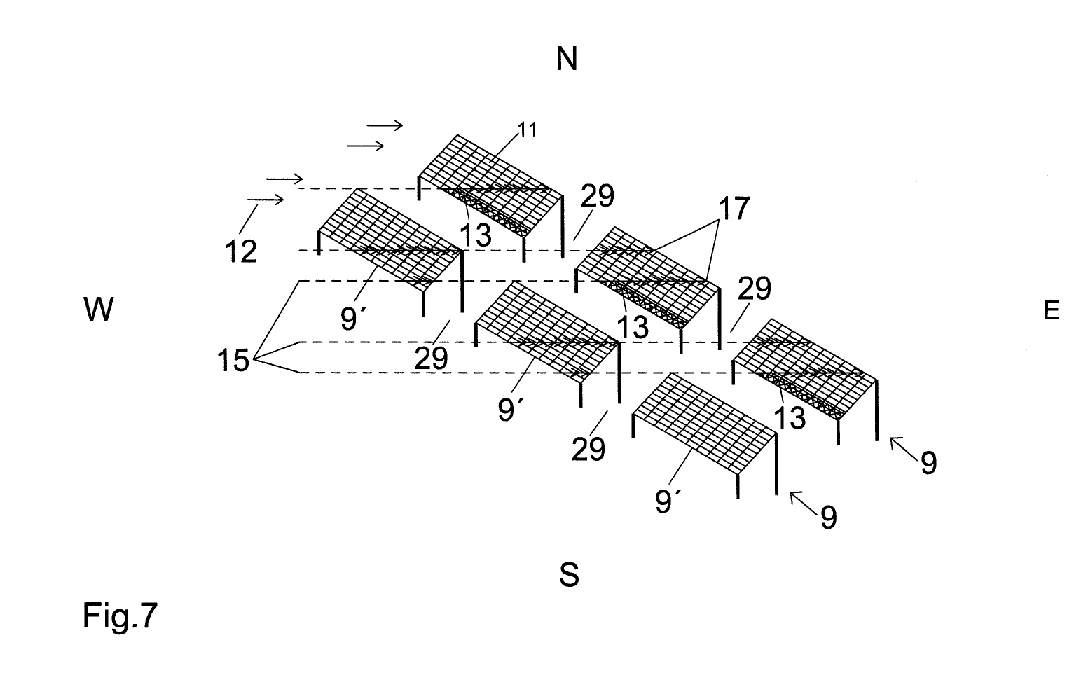

FIG. 7 shows two rows 9 arranged one behind the other, wherein each of the relevant rows 9 is divided into subsections or groups 9′ by gaps 29. A late sun position analogous to FIG. 5e is shown, in which a shadow thrown on the row 9 located in back is once again indicated symbolically by a cross-hatched area 13. The photovoltaic modules from FIGS. 6a to 6c can be used in this embodiment as well.

A photovoltaic generator in the northern hemisphere is described above. A photovoltaic generator installed in the southern hemisphere should be correspondingly aligned rotated toward the southeast.

The use of a multiple-rate meter is briefly explained below in an example. A simple supply contract comprising three rate levels is present, which states that

i) a compensation of 5 cents per KWh is provided for incoming supply until 12:00 noon,

ii) a rate of 20 cents/KWh between 12:00 noon and 4:00 P.M., and

iii) a rate of 10 cents/KWh applies thereafter until evening.

Under i), 1,000,000 KWh (GWh) were generated, which represents a reduction in output of 500,000 KWh as compared to the possible 1.5 GWh that would have been generated if the system had been installed facing south. Thus a reduction in revenue of 500,000×5 cents=25,000 Euros will result.

In contrast, in time period ii), an energy quantity of 1,400,000 KWh has been generated, which would have been only 1,200,000 KWh with the conventional alignment. Thus, an increase in incoming supply of 200,000 KWh was achieved as compared to the conventional alignment. This 200,000 KWh means an increase in income of 40,000 Euros on account of the higher rate of 20 cents/KWh. Hence, although a total of 300,000 KWh less was generated, a higher revenue was nevertheless achieved, since the generation occurred at a more “valuable” time of day.

Toward evening, during rate period iii), another increase in generation is added, because the PV generator remains better aligned with the sun until sunset. The economic result is improved further.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An outdoor photovoltaic generator comprising:
a stationary substructure; and
a plurality of substantially straight and parallel rows of rectangular photovoltaic modules that are located in a fixed manner on the stationary substructure, and each of which comprises a single string of series-connected photovoltaic cells,
wherein the photovoltaic cells are arranged on each photovoltaic module such that each photovoltaic cell of the string experiences equal shading in an event of a shading extending parallel to a bottom edge of the photovoltaic module,
wherein the stationary substructure provides substantially equal inclination of all photovoltaic modules relative to a horizontal, and
wherein the photovoltaic modules are oriented at an angle between 10° and 40° toward southwest or toward southeast.

2. An outdoor photovoltaic generator comprising:
a stationary substructure; and
a plurality of substantially straight and parallel rows of rectangular photovoltaic modules that are located in a fixed manner on the stationary substructure, and each of which comprises multiple strings of series-connected photovoltaic cells, ends of which form a first and a second output pole of the photovoltaic module,
wherein the photovoltaic cells are arranged on each photovoltaic module such that all photovoltaic cells of the same string experience equal shading in an event of a shading extending parallel to the bottom edge of the photovoltaic module,
wherein the stationary substructure provides equal inclination of all photovoltaic modules of the same string relative to the horizontal, and
wherein the photovoltaic modules are oriented at an angle between 10° and 40° toward southwest or toward southeast.

3. An outdoor photovoltaic generator with a plurality of substantially straight, parallel rows of groups, separated by a gap, each group including multiple rectangular photovoltaic modules that extend in a direction of the rows and that are located in a fixed manner on a stationary substructure, and each of which modules comprises a single string of series-connected photovoltaic cells,
wherein the photovoltaic cells are arranged on each PV module such that, for at least a portion of the PV modules in a group, each photovoltaic cell of the string experiences equal shading in the event of a shading extending parallel to the bottom edge of the PV module,
wherein the substructure provides equal inclination of all photovoltaic modules relative to the horizontal, and
wherein the photovoltaic modules are oriented at an angle between 10° and 40° toward southwest or toward southeast.

4. An outdoor photovoltaic generator with a plurality of substantially straight, parallel rows of groups, separated by a gap, each group including multiple rectangular photovoltaic modules that extend in a direction of the rows and that are located in a fixed manner on a stationary substructure, and each of which modules comprises multiple strings of series-connected photovoltaic cells, ends of which form a first and a second output pole of the photovoltaic module,
wherein the photovoltaic cells are arranged on each photovoltaic module in such a manner that, for at least a portion of the photovoltaic modules in the same group, all photovoltaic cells of the same string experience equal shading in the event of a shading extending parallel to the bottom edge of the photovoltaic module,
wherein the substructure provides equal inclination of all photovoltaic modules relative to the horizontal, and
wherein the photovoltaic modules are oriented at an angle between 10° and 40° toward southwest or toward southeast.

5. The outdoor photovoltaic generator according to claim 1, wherein the angle is between 15° and 35° or between 20° and 30°.

6. The outdoor photovoltaic generator according to claim 1, wherein the photovoltaic cells comprise stripes that extend from edge to edge of the photovoltaic modules, and wherein the edge to edge direction is substantially perpendicular to the direction of the rows.

7. The outdoor photovoltaic generator according to claim 2, wherein the photovoltaic cells of the photovoltaic modules are subdivided into multiple strings extending from edge to edge, and wherein the photovoltaic cells of each string are electrically connected in series and multiple strings of a photovoltaic module are electrically connected in parallel.

8. The outdoor photovoltaic generator according to claim 2, wherein the photovoltaic cells of the photovoltaic modules are subdivided into multiple strings arranged one behind the other and extending substantially parallel to one edge, wherein the photovoltaic cells of each string are electrically connectable in series, and wherein multiple strings of a photovoltaic module located adjacent to one another are electrically connectable in parallel.

9. The outdoor photovoltaic generator according to claim 1, wherein photovoltaic module rows are formed that have lengths between 10 m and 500 m or between 25 m and 300 m.

10. The outdoor photovoltaic generator according to claim 1, wherein the outdoor photovoltaic generator is connectable to a multiple-rate metering system, wherein the multiple-rate metering system assigns predefinable rates to the quantities of energy generated at different times of day and/or times of year.
